(19) United States
(12) Patent Application Publication
(10) Pub. No.: US 2023/0289506 A1
(43) Pub. Date: Sep. 14, 2023

(54) INSTANT PROTOTYPING SYSTEM

(71) Applicant: BLEB TECHNOLOGY SRL, PRATO (IT)

(72) Inventors: Fabrizio INNOCENTI, PRATO (IT); Lorenzo INNOCENTI, PRATO (IT)

(21) Appl. No.: 18/019,259

(22) PCT Filed: Aug. 10, 2021
(86) PCT No.: PCT/IB2021/057374

§ 371 Date: Feb. 2, 2023

(30) Foreign Application Priority Data
Aug. 10, 2020 (IT) 102020000019933

(51) Int. Cl. G06F 30/36; G06F 9/4401

(52) U.S. Cl. CPC G06F 30/36; G06F 9/4415

(57) ABSTRACT

The present invention relates to an improvement of a patent owned by the same applicant, whose sector of interest is that of electronics and prototyping inherent therein, specifically the previous invention was a promoter of the sector of rapid prototyping in the electronic/electrical field and of micro and nanoelectronics and the present invention intends to improve the previous one in different ways.

The present invention relates to an improvement of the patent 102015000075169 owned by the same applicant, whose sector of interest is that of electronics and prototyping inherent therein, in particular the previous invention was a promoter of the sector of rapid prototyping in the electronic/electrical field and micro and nanoelectronics.

### BACKGROUND OF THE INVENTION

Even more particularly, the sector of interest of the present invention is that of the original belonging of Arduino and derivatives, the first being a well-known prototyping and development system in an Open Source environment as is Rapsberry, these are all known methods of rapid prototyping.

Summarizing the salient: these rapid prototyping platforms require skills and time to allow the necessary writing of codes and/or SW and/or manual configurations of the HW.

With reference now to the previous invention, still extremely topical with respect to the sector, the following is summarized: in the previous invention, in particular, reference was made to a rapid prototyping system in which a primary device suitable for recognizing and/or configuring modules of expansion connected to said primary device by means of self-recognition such as recognition of an ID that uniquely identified each expansion module. The recognition of the modules allowed the self-configuration at the primary device level which, recognizing the module, dynamically assigned to these expansion modules a specific address for the communication on the bus between at least the primary device and at least one module, allowing a quick and simple use.

In a particularly advantageous way, this system allowed simple and rapid prototyping, without the need for long programming times as for Arduino and the other known ones.

The extreme simplicity and effectiveness of the system still being at the forefront of the art known up to now. However, with the development of the product, the applicant was able to refine some aspects with respect to the original version of the same, which advantageously allow for further developments with respect to the original product and system, thus allowing to propose a real “instant” prototyping (and not just “rapid”) to the market. Furthermore, thanks to these improvements, it was also possible to expand the range of “bricks” that can be used in the system and therefore expand the sector of use, which was previously not possible due to the assignment of a unique ID or address to each individual secondary module.

With reference, therefore, to the basic version of the project, the following is highlighted by reconnecting to the above discussion: the primary device and the original secondary modules were produced in a plurality of types and each type was distinguished by a unique ID, this was revealed over time sometimes disadvantageous, as this aspect did not allow to adapt the use of the new families of MEMST (Micro Electrical Mechanical Systems) to the present prototyping system (it will be explained later).

Again with reference to the previous patent, once the prototyping was completed, it was still necessary to abandon the prototype assembly to subsequently move on to the industrialization, production, testing and certification phases, thus limiting the shortness of time only to the prototyping phase. In fact, to pass from a prototype to a product, the phases of industrialization, production, testing and certification are always necessary.

With the use and refinement of the design, the inventors realized that benefits are achieved throughout the development chain from prototype to product as specified below.

A scope of the present invention is to provide a simple but effective solution to the aforementioned problems of the prior art and limitations of the previous system, albeit performing.

A scope of the present invention is therefore to enable anyone, such as for example companies and individuals even without particular technical knowledge, to be able to build their own prototypes of their devices in an “immediate” and effective way.

A further scope of the present invention is to maintain all the advantages of the invention which is being improved.

A further scope of the present invention is to allow the use in the system of several types of modules.

It is still a scope of the present invention to provide a prototyping system that is low in energy consumption, even three orders of magnitude lower than the competition.

A further scope of the present invention is to provide a prototyping system to make the entire product development cycle more efficient, thus obtaining an instant prototyping system.

### BRIEF DESCRIPTION OF THE INVENTION

With reference to the previous invention, the following is summarized with reference to the description of the originally filed figures (for which see the previous patent).

A system for electrical and electronic prototyping was described and claimed comprising at least one primary device, a terminal for interacting with at least a part of the primary device, at least one or more additional expansion modules connected to said primary device by means of connection interfaces characterized in that said expansion modules are substantially standardized modules to allow the communication and recognition of each of said expansion modules by said at least one primary device, i.e. said connection interfaces of said one or more expansion modules are mutually identical and/or compatible with each other, said modules being connected to said primary device and/or to each other, by means of said connection interfaces such as mutually combinable pins located on the expansion modules and on the primary device, to couple said modules to each other and/or to said device uniquely, said pins comprend having electrical contacts being shaped so as to fit into female cavities included in the modules, said cavities in turn comprising electrical contacts, to allow communication between the modules and the transmission of energy from the primary device to the other modules, said primary device being able to recognize and/or configure each of said expansion modules connected to said device, by means of self-recognition such as recognition of an ID that uniquely identifies each expansion module, said recognition allowing self-configuration at the primary device level which, recognizing the module, assigns dynamically to these a specific address for communication on the bus between at least said device and said at least one module allowing a quick and simple use.

In particular, it should be noted that in the known art (see patent 102015000075169) essential for the patent was the fact that “at the time of connection to the primary device, said expansion modules are recognized by said primary device by means of self-recognition such as recognition of an ID that uniquely identifies each expansion module”. Recognition through a unique ID to each single module, even of the same type or category, allowed self-configuration at the primary device level which, once recognized, the expansion module dynamically assigned to this a specific address for communication on the bus common to all devices avoiding the use of static techniques (e.g. deep Switches) and which would have required user intervention; here was therefore a configuration and a recognition at the hardware level.

A parenthesis is opened and it is defined for clarity that for the applicant in this particular case for modules of the same type or category or family we always mean here and below modules with the same functionality, for which at least one A1-n family will be defined including a nr N of modules with the same functionality and so on at least one family B1-n, C1-n etc.

Of particular importance is that this improvement essentially “overturns” this concept, in practice to optimize resources, costs, consumption and reliability, as well as to broaden the panorama of modules that can be used, thus to the advantage of keeping up with technological development that offers new solutions in a very short time, the concept of “unique identification” has been “overturned” by introducing a substantial change in the self-configuration, that is, there are no longer static IDs that uniquely identify each single module, but modules of the same type, i.e. with the same function, will be in a “category” with the same ID or address. Therefore more modules of the same category, which has been defined above as more modules with the same functionality here all have the same pre-assigned ID or base address.

So in essence the primary communication device is preconfigured to recognize the modules of the same category by means of a base ID that uniquely identifies one and only one category, so that no new ID must be assigned when the module is connected to the device, but limited to recognize it and to configure it for operation.

In essence, therefore, it is described and claimed:

A system for electrical and electronic prototyping comprising at least one primary device, a terminal for interacting with at least a part of the primary device, at least one or more additional expansion modules connected to said primary device through connection interfaces, said expansion modules are substantially standardized modules to allow the communication and recognition of said expansion modules by said at least one primary device, i.e. said modules being connected to said primary device and/or to each other, characterized in that said expansion modules being divided into categories of expansion modules which are identical to each other (A1-n; B1-n, etc), or having the same function and the modules of the same category (A1-n) all having the same ID or recognition address, said ID allowing communication on the bus between at least said device and said at least one module A1 of a category An, said communication allowing self-configuration at the primary device level which, recognizing the first module of a category, dynamically configures the operation of said A1 module of a particular category (An), allowing quick and easy use, the primary communication device is preconfigured to recognize the modules An of the same category by means of a base ID that uniquely identifies one and only one category, therefore not having to assign any new ID when connecting module A1 to the device, but merely recognizing it and dynamically configuring its operation, thus speeding up the system configuration operation, said system being instant prototipation.

For categories An, Bn, Cn. of modules means and defines modules with the same functionality all having the same pre-assigned ID, so each category A1-n having a pre-assigned ID, as well as each category B1-etc.

Note that in the previous version modules of the same type or category had all assigned a different ID to each other, making system configuration difficult. This also happens for the art document US 2007/294443.

On the contrary, in the present version modules of the same type all have the same identification and address, this greatly speeding up their configuration as explained above, i.e. for clarity:

At the time of connection of any module, the primary device sends an acknowledgment signal, or, in a variant, the module sends a signal at the time of connection to the primary device (this being irrelevant and known in the art), this communication only takes place between the device and a module; if the connected module is the first of a certain family, (it will only communicate its address and ID to the primary device) and the primary device (pre-configured to recognize families of modules with the same ID) will immediately configure it in terms of optimization of operation without acting on the address/ID. Therefore the activation and operation being much faster, that is instantaneous.

Instead, in the case of modules of the same type/family (A1-n) that can be used simultaneously connected to the same primary device (in instant prototyping, for example, it can happen with simple sensors such as pushbuttons or relay-type actuators) instead it happens here that:
the second module (A2) of the same family, being connected to the primary device and interrogated by it (or vice versa), receiving a “notice” of the presence of at least one other module (A1) of the same family, automatically/dynamically generates a pseudorandom identification address/ID—which is therefore not the default one—and communicates it to the primary device. (This is not broadcast, as it only transmits to the primary device and communication occurs only between them).

In particular, the primary communication device that receives the data of the new pseudorandom address generated by the second module (A2) with the same functionality (e.g. pressed button) uses the new dynamically assigned pseudorandom address to communicate with the second module (A2) of the same family.
The second module (A2) of the same family begins to function regularly with the new address assigned dynamically;
The process is repeated until new modules are identified (An or other type B, C etc.) and without the need to know a priori how many modules will be connected since the procedure is dynamic.

Consequently, it is clear why in the present invention the assignment of the same address to the same category of modules with the same functionality, when only one of them (or the first of them) is connected to the primary device, allows to save considerably time, not therefore having to require all the steps mentioned above.

Therefore, in an advantageous way, there will be dynamic assignment of a different ID between modules An of the same category only when several modules A1, A2 of the same type are inserted on the same primary device, this is obviously to recognize them with respect to the same primary device.

The use of unique addresses or IDs is therefore maintained, i.e. the assignment of unique IDs dynamically only when there are more expansion modules A1, A2, A3 of the same type An inserted on the same primary device, for example, this assignment can take place in a pseudorandom or causal way given the dynamism of the assignment.

That is, the dynamic assignment of an ID to a second module A2 of the same category An which is connected to a primary device takes place by means of random assignment, i.e. the random creation of an ID, even if it normally does not occur, when the module A2 communicates its new pseudorandom ID (while maintaining the recognition of “family” An) to the primary device in order to be connected with it, the primary device acquires it. In the (very unlikely) case in which the primary device had already connected a module with the same ID, it would not authorize the connection and the module A2 would generate a new address dynamically or pseudorandomly until it had a connection with the primary device.

Advantageously, MEMST-type modules can be used on said instant prototyping system without resorting to additional components for addressing management which would increase consumption (0.1-10 mA) and decrease reliability (by increasing the number of components).

In a further advantageous way, a variety of communication devices can be inserted into the system in addition to the primary communication devices so as to have the possibility of using more types of communication channels. Other modules external to the primary can be inserted into the system with transmitters such as: modules of the Wi-Fi type, Sigfox, NB-IoT, LoRa, etc to connect to the Internet via WAN, LP-WAN etc networks or to add additional functions, such as localization via UWB.

In a further advantageous way, the analog components and the communication ports are all on the same chip unlike the previous patent, where these parts were arranged on several discrete components separated from each other, this with the benefit of reducing consumption, thanks to the possibility of use by MEMST.

Even the programming of the pre-processing phase will always be advantageously processed by the same chip thanks to the possibility of using MEMST.

### Description of the Invention

By way of example, as previously indicated, by applying this cataloging system to the plug and play system, it will be possible to adapt the use of the above-mentioned new families of MEMST (Micro Electrical Mechanical Systems) which integrate increasingly performing sensors in a single chip equipped with serial communication port and which allow to further reduce the number of components used allowing to decrease consumption and costs, while increasing reliability, the following innovative and distinctive features are introduced with respect to the previous patent with particular reference to the self-configuration system: in fact, the address is used for communication between buses to uniquely identify the same type of modules, meaning by this modules characterized by the same and precise functionality, such as a type of modules that use the same acceleration or humidity sensor or the same type of actuator such as the same type of relay, buzzer, LED etc. or the same type of communication device such as the same Wi-Fi transceiver, UWB, Sigfox, NB-IoT, LoRa, and others.

A parenthesis opens with regard to MEMST elements: these modules advantageously integrate increasingly performing sensors. The use of micro and nanotechnologies for the realization of sensors introduces advantages that go beyond their growing miniaturization, as they not only impact on the improvement of their intrinsic performance, in terms of sensitivity, accuracy, precision and consumption, but also integrate the electronics for pre-processing and signal conditioning in a single chip equipped with a serial communication port.

Furthermore, at the system level, as mentioned above, the number of components used is reduced (for example the analogue, the preprocessing and the communication ports are all in the same chip while previously they were on more discrete components) allowing to obtain further benefits on the reduction of consumption (fewer components less parasitic capacitance in the pins and in the connection tracks and fewer additional drivers/buffers/amplifiers used in slave to the analog or digital I/O pins) costs (fewer components, less costs not only for an economic factor but also because remaining on the same chip/MEMST does not need to waste silicon to create, for example, the output pin buffers useful only for driving the greater capacitive loads of the pad pins and tracks on PCBs), while increasing reliability (fewer components=>fewer causes/probability of failure).

In fact, if on the one hand it makes practical sense to connect several identical buttons to the same primary device, eg. to signal to the DP different choices, or more identical relays, eg. to activate through them with the same DP several actuators independently (e.g. motor 1 motor 2 and motor 3) or to activate several identical LEDs, to signal several different events by virtue of positions or lenses with different colors through the same primary device, on the other hand, it makes less sense to hypothesize that two identical acceleration or humidity or CO2 sensors can be connected to the same primary device since in most cases of practical use, being often confined to contiguous spaces, they would not benefit the content informative and would weigh only on the costs and consumption of the system.

Based on these considerations the additional logic for the dynamic configuration of the address will be added only to modules that actually need it, i.e. those that are most likely to be connected to the same primary device, saving resources, reducing costs, consumption and improving the reliability of the individual modules and of the whole system.

That is, only the modules that are more likely to be mounted on the same primary device will include the additional logic of the possibility of changing their ID, such as relays, buttons and/or the like, while humidity, temperature, CO2 detection modules, which are less likely to be inserted on the same primary device, since this is essentially the size of a “box”, it is difficult for two temperature sensors, etc. to be useful at a distance of a few centimeters. Here each module category has been assigned an An, Bn, Cn, etc. numbering for convenience.

In a completely innovative and advantageous way and with a considerable difference compared to the patent application of which the present is an improvement, with the new instant prototyping system it is possible to obtain, in particular, an advantage for:
industrialization, necessary to transform the prototype into a product with optimized costs, form factors, performance and consumption, a set of HW, FW and SW primitives that characterize each module is reused (e.g. connections and PCB layout for the HW part, FW for the management of the single sensors and actuators used in the modules with the SOC used in the DP, SW for the communication of the data coming from sensors and commands for actuators by the terminal) and are already prepared and verified for the functioning of the whole. To obtain an industrialized version of the prototype on a practical level, it is normally only necessary to remove the redundancies common to the various modules, such as connectors, additional logic for managing bus connections, etc., which are necessary to create the present instantaneous prototyping system, and therefore reassemble the primitives by joining them together to obtain the constructive models of the HW and functional models of the FW and SW of the industrialized device. The times for this process are reduced to hours, maximum days, against the weeks and months required by the state of the art.
production and testing, predefined production and procurement processes are reused, already validated and started to manage this type of production, drawing logistical and economic advantages from orders made on a larger scale (similar components are used for modules and industrialized devices). Even the equipment and testing procedures are reusable on various projects as the same modules are always used
certification: already certified parent modules are reused, saving costs and time necessary for certification, eg. for RED tests.

For practical purposes, this has made it possible to introduce further advantages, which become strengths with respect to the competition and materialize in the offer of a Fast Route to Production service, or an efficient industrialization and production service capable of cutting down on average times and development costs of 90% compared to competing solutions.

It should be noted, in a further advantageous way, that other communication devices can be inserted in the system, i.e. communication does not take place only through the primary devices. It is therefore advantageously possible to have other communication modules apart from the classical primary communication modules already described above. For practical applications, advantageously, other modules external to the primary with transreceiver can be inserted into the system such as: modules of the Wi-Fi type, Sigfox, NB-IoT, LoRa, etc to connect to the Internet via WAN, LP-WAN, etc. networks or add additional features, such as localization via UWB.

The system becomes to all intents and purposes an “instant” prototyping system with all the related advantages evident to every operator in the sector.

Finally, with reference to patents of a similar application area, the following is commented: the art document US 2007/294443 defines a possible mechanism for assigning in broadcast different ADDRESSES to the expansion slave modules that are pre-characterized by different IDs that distinguish them (basically, the primary device broadcasts a device ID and if the module has the same ID the Bus Address included in the broadcast message is assigned to the slave)

In the present invention we speak of assigning different IDs not in broadcast and not to pre-defined addresses and only by dynamically assigning IDs when needed i.e. if there are other identical modules. A substantial difference is that in the present invention the address for communication between buses is used to uniquely identify the same type of modules, meaning by this modules characterized by the same and precise functionality.

Therefore the broadcast mechanism is neither necessary nor relevant for the development/implementation of the present invention since the present invention uses another working mechanism.

Document US2016/292090 does not describe a method for assigning addresses that are already known and resolved upstream by the BUS manager, in fact said patent provides for a priori static writing of information regarding the elements to be addressed also in this case, then one proceeds with a broadcast command to all peripherals. In our patent, on the other hand, as described several times, the assignment takes place dynamically (not statically) which is why there is no information written on a physical memory that can give information regarding the addresses of the connected devices.

For each specific technical detail not explored here, reference should be made to the patent granted 102015000075169 where the parts in common with this improvement are described in detail.

These are just some of the possible and advantageous embodiments of the innovative system for instant industrial prototyping described by the present invention. It should be noted that, each variant in size of the parts making up the system, shape, material, type of connection interface between the modules and with the terminal whether they are physical or non-physical, number of parts included in the device or other means that make the elements function constitutive herein described, are to be considered the object of the present invention as better described by the attached claims.

1. System for electrical and electronic prototyping comprising at least one primary device, a terminal for interacting with at least a part of the primary device, at least one or more additional expansion modules connected to said primary device through connection interfaces, said expansion modules are substantially standardized modules to allow the communication and recognition of said expansion modules by said at least one primary device, or said modules being connected to said primary device and/or to each other, characterized in that said expansion modules being divided into categories of expansion modules equal to each other (A1-n; B1-n, etc), i.e. having the same function and modules of the same category having the same ID or recognition address, said ID allowing communication on the bus between at least said device and at least one module (A1) of the same category (An), said communication allowing the self-configuration at the primary device level which, recognizing the first module (A1) of a particular category (An), dynamically configures the operation of said module of a particular category, allowing a quick and simple use, the primary communication device being in fact pre-configured to recognize the modules (An) of the same category by means of a base ID that uniquely identifies one and only one category (An), so that no new ID must be assigned to the device when the first module (A1) is connected but merely recognizing it, this speeding up the configuration operation of the system, said system being instantaneous prototyping.

2. The system for electrical and electronic prototyping according to claim 1, in which by categories (An, Bn, Cn) or type of modules we mean and define modules with the same functionality all having the same pre-assigned ID, for which each category (An) having a pre-assigned ID, as well as any category (Bn) etc.

3. The system for electrical and electronic prototyping according to the preceding claims, in which dynamic assignment of a different ID is carried out between modules (A1, A2, An) of the same type only when more than one module (An) is connected to the same primary device type, this to recognize each other, therefore the use of assignment of unique addresses or IDs is maintained dynamically for each module, i.e. the assignment of unique IDs for each module even if of the same category, only when there are more modules of the same type (An) inserted on the same primary device.

4. The system for electrical and electronic prototyping according to the previous claims, in which the dynamic assignment of a unique address/ID to a module (A1) of the same category (An), in case of connection of two or more modules of the same category family (An) to the primary device occurs pseudorandomly.

5. The system for electrical and electronic prototyping according to the preceding claims, in which MEMST-type modules can be used on said instant prototyping system without resorting to additional components for addressing management, for the benefit of reduced consumption and increased reliability since also to said MEMST is assigned a unique address or ID for each type or category of the same, therefore not requiring recognition logics for IDs assigned individually to each module even in the same category.

6. The system for electrical and electronic prototyping according to the preceding claims, in which a variety of communication devices can be inserted in said system in addition to the primary communication devices so as to have the possibility of using more types of communication channels.

7. The system for electrical and electronic prototyping according to the previous claims, in which other modules external to the primary with transmitters can be inserted into the system such as: Wi-Fi, Sigfox, NB-IoT, LoRa, etc modules to connect to the Internet via WAN, LP-WANs etc networks or to add additional functions, such as localization via UWB, therefore the communication taking place not only via primary devices.

8. The system for electrical and electronic prototyping according to the previous claims, in which in the MEMST modules the analog components and the communication ports are all on the same chip, therefore reducing the number of components used such as analog, pre-processing and having all the communication ports in the same chip (while before they were on more discrete components) further benefits are obtained on the reduction of consumption since fewer components imply less parasitic capacitance in the pins and in the connection tracks and fewer additional drivers/buffers/amplifiers used in interlocking to the analog or digital I/O pins, whether they are.

9. The system for electrical and electronic prototyping according to the preceding claims, in which the programming of the pre-processing phase will be processed by the same chip using MEMST modules.

10. The system for electrical and electronic prototyping according to the previous claims, in which the additional logic for the dynamic configuration of the address will be added only to categories of modules (An or Bn or Cn) that actually need it, that is, those that are most likely to be connected to the same primary device more than one, saving resources, reducing costs, consumption and improving the reliability of the individual modules and of the entire system.
